(19) United States
(12) Patent Application Publication
(10) Pub. No.: US 2014/0014914 A1
(43) Pub. Date: Jan. 16, 2014

(54) ORGANIC LIGHT-EMITTING DISPLAY DEVICE AND METHOD OF MANUFACTURING THE SAME

(71) Applicants: Yul-Kyu LEE, Yongin-City (KR); Sun PARK, Yongin-City (KR); Kyu-Sik CHO, Yongin-City (KR); Ji-Hoon SONG, Yongin-City (KR)

(72) Inventors: Yul-Kyu LEE, Yongin-City (KR); Sun PARK, Yongin-City (KR); Kyu-Sik CHO, Yongin-City (KR); Ji-Hoon SONG, Yongin-City (KR)

(21) Appl. No.: 13/755,339

(22) Filed: Jan. 31, 2013

(30) Foreign Application Priority Data
Jul. 10, 2012 (KR) 10-2012-0075144

(51) Int. Cl. H01L 51/52

(52) U.S. Cl. CPC H01L 51/5203; H01L 51/52
USPC 257/40; 257/99; 257/88; 438/22

(57) ABSTRACT

An organic light-emitting display device includes a substrate, a first electrode on the substrate, a particle located between the substrate and the first electrode, an insulation pattern that is on the first electrode and that corresponds to the particle, an intermediate layer that is on the insulation pattern and that is electrically connected to the first electrode, the intermediate layer including an organic emission layer, and a second electrode on the intermediate layer.

### CROSS-REFERENCE TO RELATED PATENT APPLICATION

This application claims the benefit under 35 U.S.C. §119 of Korean Patent Application No. 10-2012-0075144, filed on Jul. 10, 2012, in the Korean Intellectual Property Office, the disclosure of which is incorporated herein in its entirety by reference.

### BACKGROUND

1. Field

Embodiments relate to an organic light-emitting display device and a method of manufacturing the same.

2. Description of the Related Art

Organic light-emitting display devices are self-emissive display devices having wide viewing angles, an excellent contrast ratio, and high response times. Thus, organic light-emitting display devices are regarded as next-generation display devices.

An organic light-emitting display device includes an intermediate layer between a first electrode and a second electrode. The intermediate layer includes an organic emission layer (EML). When a voltage is applied to the first and second electrodes, a visible ray is generated in the organic EML.

### SUMMARY

Embodiments are directed to an organic light-emitting display device including a substrate, a first electrode on the substrate, a particle located between the substrate and the first electrode, an insulation pattern that is on the first electrode and that corresponds to the particle, an intermediate layer that is on the insulation pattern and that is electrically connected to the first electrode, the intermediate layer including an organic emission layer, and a second electrode on the intermediate layer.

The insulation pattern may have a greater width than the particle such that the particle does not exceed the insulation pattern in size.

The first electrode may include a protruding region corresponding to the particle. The insulation pattern covers the protruding region of the first electrode. The first electrode may include a first region, a second region, and an opening region. The first region and the second region may be spaced apart from each other by the opening region. The opening region may have a greater width than the particle and surrounds the particle. The first region may correspond to the particle and may be spaced apart from the intermediate layer. The second region contacts the intermediate layer. The insulation pattern may fill the opening region.

Embodiments are also directed to an organic light-emitting display device including a substrate in which a display area including a plurality of pixels, and a non-display area that surrounds the display area are defined, each of the plurality of pixels including a first electrode, an intermediate layer including an organic emission layer, and a second electrode, a particle located in at least one of the plurality of pixels between the substrate and the first electrode, and an insulation pattern that is on the first electrode and that corresponds to the particle.

The insulation pattern may have a greater width than the particle such that the particle does not exceed the insulation pattern in size.

The first electrode may include a protruding region corresponding to the particle. The insulation pattern may cover the protruding region of the first electrode. The first electrode may include a first region, a second region, and an opening region. The first region and the second region may be spaced apart from each other by the opening region. The opening region may have a greater width than the particle and surrounds the particle. The first region may correspond to the particle and may be spaced apart from the intermediate layer. The second region may contact the intermediate layer. The insulation pattern may fill the opening region.

The organic light-emitting display device may further include a thin film transistor (TFT) that is electrically connected to the first electrode of each of the plurality of pixels and that includes an active layer, a gate electrode, a source electrode, and a drain electrode.

Each pixel of the plurality of pixels may include a thin film transistor (TFT) that is electrically connected to the first electrode of the respective pixel and that includes an active layer, a gate electrode, a source electrode, and a drain electrode. The first electrode may be formed on the same layer as the gate electrode.

Embodiments are also directed to a method of manufacturing an organic light-emitting display device including forming a first electrode on a substrate, detecting the presence of a particle between the substrate and the first electrode, forming an insulation pattern on the first electrode such that the insulation pattern corresponds to the particle, forming an intermediate layer that is disposed on the insulation pattern and electrically connected to the first electrode, the intermediate layer including an organic emission layer, and forming a second electrode on the intermediate layer. The detecting of the presence of the particle may include determining an existence, a size, a shape, and a position of the particle.

The insulation pattern may have a width greater than the particle such that the particle does not exceed the insulation pattern in size.

The first electrode may include a protruding region corresponding to the particle. The insulation pattern covers the protruding region of the first electrode.

The first electrode may include a first region, a second region, and an opening region. The first region and the second region may be spaced apart from each other by the opening region. The opening region may have a greater width than the particle and surrounds the particle. The opening region may be formed via a cutting process. The cutting process may be performed using a laser beam. The first region may correspond to the particle and may be spaced apart from the intermediate layer. The second region may contact the intermediate layer. The insulation pattern may fill the opening region.

The method may further include forming a thin film transistor (TFT) that is electrically connected to the first electrode and that includes an active layer, a gate electrode, a source electrode, and a drain electrode.

The method may further include forming a TFT that is electrically connected to the first electrode and that includes an active layer, a gate electrode, a source electrode, and a drain electrode. The first electrode may be formed on the same layer as the gate electrode. The detecting of the particle may be performed after the source electrode and the drain electrode are formed

### BRIEF DESCRIPTION OF THE DRAWINGS

The above features will become more apparent by describing in detail exemplary embodiments thereof with reference to the attached drawings in which:

FIG. 1 is a plane view of an organic light-emitting display device according to an embodiment;

FIG. 2 is a magnified view of region A of FIG. 1;

FIG. 3 is a cross-sectional view of the organic light-emitting display device, taken along line of FIG. 2;

FIG. 4 is a cross-sectional view of an organic light-emitting display device according to another embodiment;

FIG. 5 is a cross-sectional view of an organic light-emitting display device according to another embodiment;

FIG. 6 is a cross-sectional view of an organic light-emitting display device according to another embodiment;

FIG. 7 is a plane view of an organic light-emitting display device according to another embodiment;

FIG. 8 is a magnified view of region A of FIG. 7;

FIG. 9 illustrates in detail a particle and an insulation pattern of FIG. 8;

FIG. 10 is a cross-sectional view of the organic light-emitting display device, taken along line X-X of FIG. 8;

FIGS. 11A through 11E are cross-sectional views of stages of a method of manufacturing the organic light-emitting display device of FIG. 1, according to an embodiment; and

FIGS. 12A through 12D are cross-sectional views of stages of a method of manufacturing the organic light-emitting display device of FIG. 10, according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

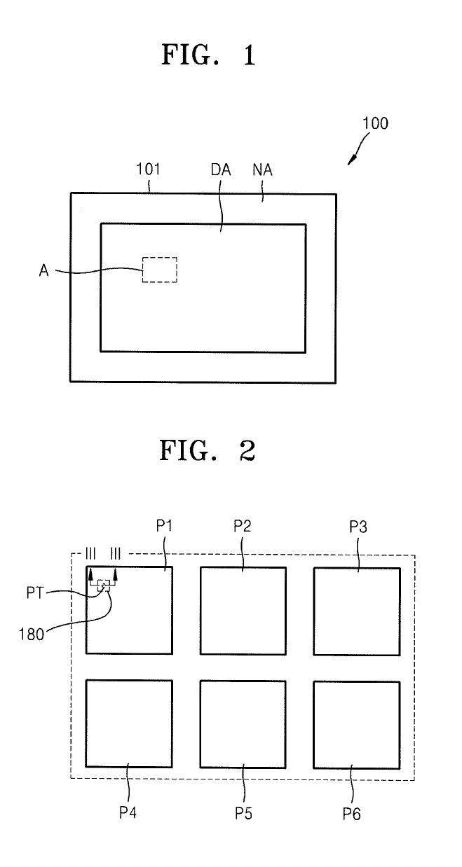

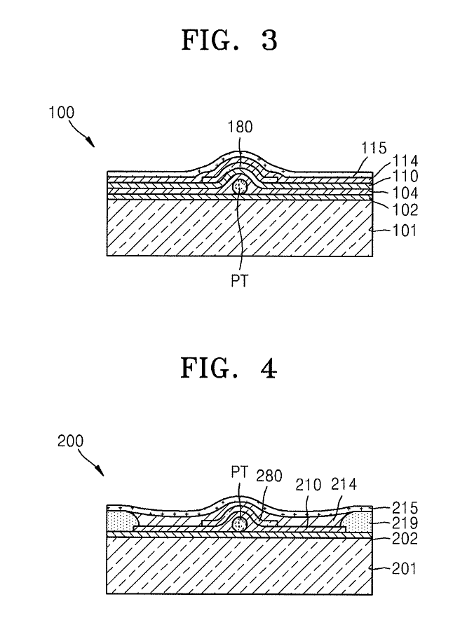

FIG. 1 is a plane view of an organic light-emitting display device 100 according to an embodiment. FIG. 2 is a magnified view of region A of FIG. 1. FIG. 3 is a cross-sectional view of the organic light-emitting display device 100, taken along line of FIG. 2.

Referring to FIGS. 1 through 3, the organic light-emitting display device 100 includes a substrate 101 in which a display area DA and a non-display area NA are defined.

In the display area DA, a plurality of pixels P1, P2, P3, P4, P5, and P6 are formed. Each of the pixels P1, P2, P3, P4, P5, and P6 includes a first electrode 110, an insulation pattern 180, an intermediate layer 114, and a second electrode 115. At least one of the plurality of pixels P1, P2, P3, P4, P5, and P6 may include a particle PT.

Hereinafter, each member will be described in detail.

The substrate 101 may be formed of a transparent glass material containing SiO₂ as a main component. In another implementation, the substrate 101 may be formed of a transparent plastic material.

A buffer layer 102 is formed on the substrate 101. The buffer layer 102 prevents moisture and foreign substances from entering into the substrate 101 and provides a flat surface on the substrate 101. The buffer layer 102 may be formed by using one of various materials capable of performing the aforementioned functions. For example, the buffer layer 102 may include inorganic materials such as silicon oxide, silicon nitride, silicon oxynitride, aluminum oxide, aluminum nitride, titanium oxide, titanium nitride, or the like, may include organic materials such as polyimide, polyester, acryl, or the like, or may be a composite layer formed of a plurality of materials selected from the aforementioned materials. The buffer layer 102 may be omitted.

The particle PT may be present on the buffer layer 102. The particle PT is not included in a design condition of the organic light-emitting display device 100, but instead, may be undesirably formed during a manufacturing process. The particle PT may be an organic material, an inorganic material, or a metal material. For example, undesired particles PT may be generated in a process of manufacturing the organic light-emitting display device. Examples of the particles PT include residual products generated while components of the organic light-emitting display device are formed, foreign substances penetrating from outside, or the like.

An insulating layer 104 is formed on the particle PT so as to cover the particle PT. The insulating layer 104 may be formed above various lines (not shown) or electrodes (not shown) which are arranged in the pixel P1, and may be formed of various insulating materials. The insulating layer 104 may be omitted.

Although not illustrated, the particle PT may be present on the insulating layer 104, or may be between the substrate 101 and the buffer layer 102, instead of directly on the buffer layer 102.

The first electrode 110 is formed on the insulating layer 104. The first electrode 110 may be formed of ITO, IZO, ZnO, or In₂O₃. In other implementations, the first electrode 110 may be formed of metal including Ag, Mg, Al, Pt, Pd, Au, Ni, Nd, Ir, Cr, Li, Yb, or Ca.

The first electrode 110 is not flat due to presence of the particle PT formed therebelow. Thus, the first electrode 110 may have a protruding shape. In particular, depending on the size of the particle PT, the first electrode 110 may have a large protruding region that corresponds to the particle PT.

The insulation pattern 180 is formed on the first electrode 110. In more detail, the insulation pattern 180 is formed to correspond to the particle PT. Also, as illustrated in FIGS. 2 and 3, the insulation pattern 180 on the first electrode 110 overlaps with the particle PT and has a greater width than the particle PT. In FIG. 2, the insulation pattern 180 is shown as having a quadrangular shape but other shapes are possible. The insulation pattern 180 may have one of various shapes that overlap with the particle PT and have a greater width than the particle PT.

The intermediate layer 114 is formed on the insulation pattern 180. The intermediate layer 114 includes an organic emission layer (organic EML) to emit a visible ray. The organic EML of the intermediate layer 114 may be formed as a small-molecule organic material or a polymer organic material. When the organic EML of the intermediate layer 114 is formed of a small-molecule organic material, the intermediate layer 114 may include a hole injection layer (HIL), a hole transport layer (HTL), the organic EML, an electron transport layer (ETL), an electron injection layer (EIL), and the like.

The HIL may be formed of a phthalocyanine compound including copper phthalocyanine, or may be a starburst-type amine such as TCTA, m-MTDATA, m-MTDAPB, or the like.

The HTL may be formed of N,N′-bis(3-methylphenyl)-N,N′-diphenyl-[1,1-biphenyl]-4,4′-diamine (TPD), N,N′-di(naphthalene-1-yl)-N,N′-diphenyl benzidine (a-NPD), or the like.

The EIL may be formed of lithium fluoride (LiF), sodium chloride (NaCl), cesium fluoride (CsF), lithium oxide (Li₂O), barium oxide (BaO), or lithium quinolate (Liq).

The ETL may be formed of aluminum tris(8-hydroxyquinoline) (Alq3).

The organic EML may include a host material and a dopant material. Examples of the host material of the organic EML may include tris(8-hydroxy-quinolinato)aluminum (Alq3), 9,10-di(naphth-2-yl)anthracene (ADN), 3-tert-butyl-9,10-di(naphth-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), 1,3-bis(carbazol-9-yl)benzene (mCP), 1,3,5-tris(carbazol-9-yebenzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol)fluorene (FL-4CBP), 4,4′-bis(carbazol-9-yl)-9,9-di-tolyl-fluorene (DPFL-CBP), 9,9-bis(9-phenyl-9H-carbazol)fluorene (FL-2CBP), or the like. Examples of the dopant material of the organic EML may include 4,4′-bis[4-(di-p-tolylamino)styryl]biphenyl (DPAVBi), 9,10-di(naphth-2-yl)anthracene (ADN), 3-tert-butyl-9,10-di(naph-2-tyl)anthracene (TBADN), or the like.

The second electrode 115 is formed on the intermediate layer 114. The second electrode 115 may be formed of metal including Ag, Mg, Al, Pt, Pd, Au, Ni, Nd, Ir, Cr, Li, or Ca. In other implementations, the second electrode 115 may be formed of ITO, IZO, ZnO, or In₂O₃.

An encapsulation member (not shown) may be further formed on the second electrode 115. The encapsulation member protects the first electrode 110, the intermediate layer 114, or the second electrode 115 against moisture, foreign substances, shock, or the like. The encapsulation member may be formed of various materials. The encapsulation member may be formed by using a glass substrate or by stacking an organic material or an inorganic material.

In the organic light-emitting display device 100 according to the present embodiment, the insulation pattern 180 is formed between the first electrode 110 and the intermediate layer 114. The insulation pattern 180 easily prevents a defect such as a dark spot due to the particle PT.

In more detail, the undesired particle PT may be present between the substrate 101 and the first electrode 110. Due to the presence of the particle PT, the first electrode 110 has a protruding region at a position that corresponds to the particle PT. If the insulation pattern 180 were not included, the protruding region of the first electrode 110 could not only contact the intermediate layer 114 but also could partially contact the second electrode 115 due to a height of the protruding region. As a result, a short circuit defect could occur between the first electrode 110 and the second electrode 115. A defect such as a dark spot could occur in the corresponding pixel P1. That is, an entire region of the pixel P1 having the particle PT may not emit light.

However, according to the present embodiment, the insulation pattern 180 is formed on the first electrode 110 so as to correspond to the particle PT. Thus, although the first electrode 110 has the protruding region, the protruding region contacts the insulation pattern 180, so that it may be possible to fundamentally prevent the protruding region of the first electrode 110 from contacting the intermediate layer 114 and the second electrode 115.

In a region of the pixel P1 in which the particle PT is present, light is normally emitted except for in a region in which the insulation pattern 180 is formed. Thus, although the particle PT is present, a defect such as a dark spot of the pixel P1 may be effectively prevented, so that an image quality characteristic of the organic light-emitting display device 100 may be easily improved.

In addition, the insulation pattern 180 may be a region in which emission of the pixel P1 does not occur. Accordingly, the insulation pattern 180 may not be excessively large.

FIG. 4 is a cross-sectional view of an organic light-emitting display device 200 according to another embodiment. For convenience of description, the present embodiment will be described with respect to differences from the previous embodiment.

Referring to FIG. 4, the organic light-emitting display device 200 includes a substrate 201 in which a display area (not shown) and a non-display area (not shown) are defined.

A plurality of pixels (not shown) are formed in the display area, and each of the pixels includes a first electrode 210, an insulation pattern 280, an intermediate layer 214, and a second electrode 215. At least one of the plurality of pixels includes a particle PT.

A buffer layer 202 is formed on the substrate 201. As in the previous embodiment, the buffer layer 202 may be omitted.

The particle PT may be present on the buffer layer 202. The first electrode 210 is formed on the particle PT so as to cover the particle PT. An insulating layer (not shown) may be formed on the buffer layer 202 as in the previous embodiment.

The first electrode 210 is not flat due to the particle PT present therebelow and thus has a protruding shape. In particular, depending on a size of the particle PT, the first electrode 210 may have a large protruding region that corresponds to the particle PT.

The insulation pattern 280 is formed on the first electrode 210. In more detail, the insulation pattern 280 is formed to correspond to the particle PT. Also, the insulation pattern 280 on the first electrode 210 overlaps with the particle PT and has a greater width than the particle PT. The insulation pattern 280 may have one of various shapes that overlap with the particle PT and are greater in width than the particle PT.

A pixel-defining layer (PDL) 219 is formed to cover a side end of the first electrode 210. The PDL 219 is formed of an insulating material and does not cover a predetermined region of a top surface of the first electrode 210.

The intermediate layer 214 is formed on the insulation pattern 280. The intermediate layer 214 includes an organic EML to emit a visible ray.

The second electrode 215 is formed on the intermediate layer 214. Also, an encapsulation member (not shown) may be further formed on the second electrode 215.

In the organic light-emitting display device 200 according to the present embodiment, the insulation pattern 280 is formed between the first electrode 210 and the intermediate layer 214. The insulation pattern 280 may easily prevent a defect such as a dark spot due to the particle PT.

Thus, an image quality characteristic of the organic light-emitting display device 200 may be easily improved.

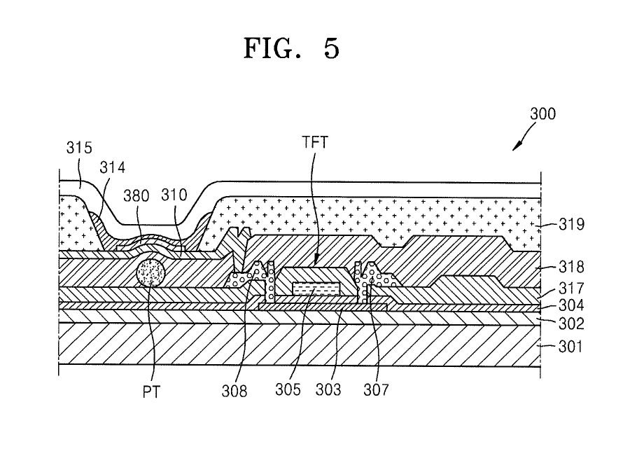

FIG. 5 is a cross-sectional view of an organic light-emitting display device 300 according to another embodiment. For convenience of description, the present embodiment will be described with respect to differences from the previous embodiment.

Referring to FIG. 5, the organic light-emitting display device 300 includes a substrate 301 in which a display area (not shown) and a non-display area (not shown) are defined.

A plurality of pixels (not shown) are formed in the display area. Each of the pixels includes a first electrode 310, an insulation pattern 380, an intermediate layer 314, and a second electrode 315. At least one of the pixels includes a particle PT.

Also, each pixel of the organic light-emitting display device 300 may include a thin film transistor (TFT) that is electrically connected to the first electrode 310. The TFT includes an active layer 303, a gate electrode 305, a source electrode 307, and a drain electrode 308.

Hereinafter, each member of the organic light-emitting display device 300 will be described in detail.

A buffer layer 302 is formed on the substrate 301. As in the previous embodiment, the buffer layer 302 may be omitted.

The active layer 303 having a predetermined pattern is formed on the buffer layer 302. The active layer 303 may be formed of an inorganic semiconductor such as amorphous silicon or polysilicon, or an organic semiconductor.

A gate insulating layer 304 is formed on the active layer 303. The gate electrode 305 is formed on a predetermined region of a top surface of the gate insulating layer 304. The gate insulating layer 304 may insulate the gate electrode 305 from the active layer 303 and may be formed of an organic material or an inorganic material such as SiNₓ or SiO₂.

The gate electrode 305 may be formed by using various materials, in consideration of adhesion, planarization, electrical resistance, formability, or the like with respect to neighboring layers. For example, the gate electrode 305 may be formed of a metal selected from the group of Au, Ag, Cu, Ni, Pt, Pd, Al, and Mo, or may be formed of a metal alloy such as Al—Nd alloy, Mo—W alloy, and the like.

An interlayer insulating layer 317 is formed on the gate electrode 305. The interlayer insulating layer 317 and the gate insulating layer 304 are formed to expose a predetermined region of the active layer 303. The source electrode 307 and the drain electrode 308 contact the exposed region of the active layer 303.

The source electrode 307 and the drain electrode 308 may be formed of various conductive materials and may have a single layer structure or a multi-layered structure.

The particle PT may be present on the interlayer insulating layer 317. Although not illustrated, the particle PT may be present at various positions. The particle PT may be present on the substrate 301, the buffer layer 302, or the gate insulating layer 304, and a plurality of the particles PT may be present.

A passivation layer 318 is formed on the TFT. In more detail, the passivation layer 318 is formed on the source electrode 307 and the drain electrode 308. The passivation layer 318 is also formed on the particle PT, and has a protruding region corresponding to the particle PT.

The passivation layer 318 does not completely cover the drain electrode 308 and exposes a predetermined region of the drain electrode 308. The first electrode 310 is connected to the exposed region of the drain electrode 308.

The insulation pattern 380 is formed on the first electrode 310. In more detail, the insulation pattern 380 is formed to correspond to the particle PT. Also, the insulation pattern 380 on the first electrode 310 overlaps with the particle PT and has a greater width than the particle PT. The insulation pattern 380 may have one of various shapes that overlap with the particle PT and have a greater width than the particle PT.

A PDL 319 formed of an insulating material is formed on the first electrode 310. The PDL 319 exposes a predetermined region of the first electrode 310, and the intermediate layer 314 contacts the exposed region of the first electrode 310. Also, the second electrode 315 is connected to the intermediate layer 314.

An encapsulation member (not shown) may be further formed on the second electrode 315.

In the present embodiment, the first electrode 310 is not flat due to the presence of the particle PT formed therebelow, and thus has a protruding shape. In particular, depending on a size of the particle PT, the first electrode 310 may have a large protruding region that corresponds to the particle PT.

In the organic light-emitting display device 300 according to the present embodiment, the insulation pattern 380 is formed between the first electrode 310 and the intermediate layer 314. The insulation pattern 380 easily prevents a defect such as a dark spot due to presence of the particle PT.

Thus, an image quality characteristic of the organic light-emitting display device 300 is easily improved.

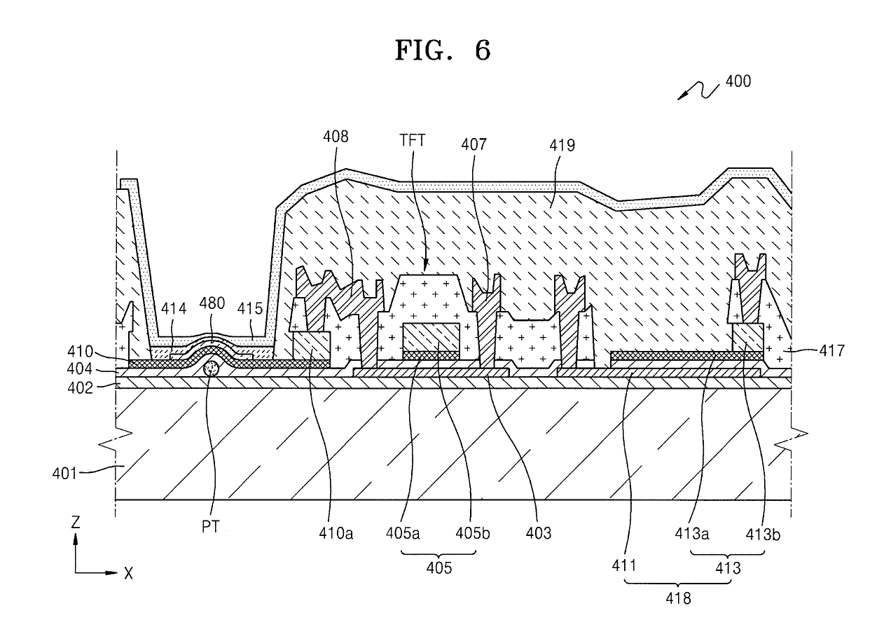

FIG. 6 is a cross-sectional view of an organic light-emitting display device 400 according to another embodiment. For convenience of description, the present embodiment will be described with respect to differences from the previous embodiment.

Referring to FIG. 6, the organic light-emitting display device 400 includes a substrate 401 in which a display area (not shown) and a non-display area (not shown) are defined.

A plurality of pixels (not shown) are formed in the display area. Each of the pixels includes a first electrode 410, an insulation pattern 480, an intermediate layer 414, and a second electrode 415. A particle PT is present in at least one of the pixels.

Also, the organic light-emitting display device 400 includes a TFT and a capacitor 418 which are electrically connected to the first electrode 410. The TFT includes an active layer 403, a gate electrode 405, a source electrode 407, and a drain electrode 408.

A buffer layer 402 is formed on the substrate 401. The active layer 403 having a predetermined size is formed on the buffer layer 402. Also, a first capacitor electrode 411 is formed on the buffer layer 402. The first capacitor electrode 411 may be formed of the same material as the active layer 403.

The particle PT may be present on the buffer layer 402.

A gate insulating layer 404 is formed to cover the active layer 403 and the first capacitor electrode 411. The gate insulating layer 404 may cover the particle PT, or may not cover the particle PT if the particle PT is large.

Although not illustrated, the particle PT may be present on the substrate 401 or the gate insulating layer 404.

The gate electrode 405, the first electrode 410, and a second capacitor electrode 413 are formed on the gate insulating layer 404.

The gate electrode 405 includes a first conductive layer 405a and a second conductive layer 405b.

The first electrode 410 may be formed of the same material as the first conductive layer 405a. A conductive part 410a is disposed on a predetermined region of a top surface of the first electrode 410. The conductive part 410a is formed of the same material as the second conductive layer 405b.

The second capacitor electrode 413 includes a first layer 413a and a second layer 413b. The first layer 413a is formed of the same material as the first conductive layer 405a, and the second layer 413b is formed of the same material as the second conductive layer 405b. The second layer 413b has a size less than a size of the first layer 413a and is formed on the first layer 413a. The second capacitor electrode 413 overlaps with the first capacitor electrode 411 and has a size less than a size of the first capacitor electrode 411.

An interlayer insulating layer 417 is formed on the first electrode 410, the gate electrode 405, and the second capacitor electrode 413. The source electrode 407 and the drain electrode 408 are formed on the interlayer insulating layer 417. The source electrode 407 and the drain electrode 408 are connected to the active layer 403.

One of the source electrode 407 and the drain electrode 408 is electrically connected to the first electrode 410, and referring to FIG. 6, the drain electrode 408 is electrically connected to the first electrode 410. In more detail, the drain electrode 408 contacts the conductive part 410a.

The insulation pattern 480 is formed on the first electrode 410. In more detail, the insulation pattern 480 corresponds to the particle PT. The insulation pattern 480 on the first electrode 410 overlaps with the particle PT and has a greater width than the particle PT. The insulation pattern 480 may have one of various shapes that overlap with the particle PT and are greater in width than the particle PT.

A PDL 419 is formed on the interlayer insulating layer 417 so as to cover the source electrode 407, the drain electrode 408, and the capacitor 418.

The PDL 419 has an opening that corresponds to a top surface of the first electrode 410, and the intermediate layer 414 is formed on the first electrode 410 that is exposed via the opening of the PDL 419.

The second electrode 415 is formed on the intermediate layer 414. Although not illustrated, an encapsulation member (not shown) may be formed on the second electrode 415.

In the present embodiment, the first electrode 410 is not flat due to the particle PT present therebelow and thus has a protruding shape. In particular, depending on the size of the particle PT, the first electrode 410 may have a large protruding region that corresponds to the particle PT.

In the organic light-emitting display device 400 according to the present embodiment, the insulation pattern 480 is formed between the first electrode 410 and the intermediate layer 414. The insulation pattern 480 may easily prevent a defect such as a dark spot due to the presence of the particle PT.

Thus, an image quality characteristic of the organic light-emitting display device 400 may be easily improved.

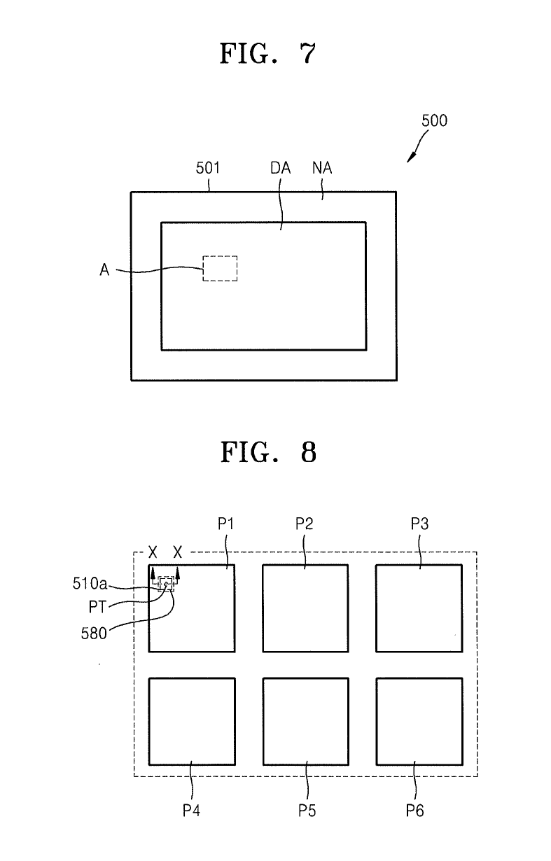

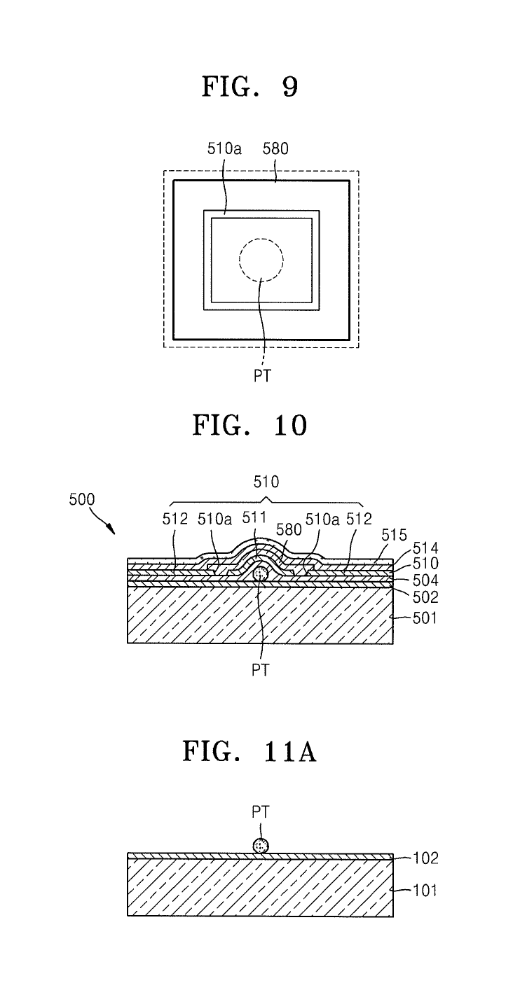

FIG. 7 is a plane view of an organic light-emitting display device 500 according to another embodiment. FIG. 8 is a magnified view of region A of FIG. 7. FIG. 9 illustrates in detail a particle PT and an insulation pattern 580 of FIG. 8. FIG. 10 is a cross-sectional view of the organic light-emitting display device 500, taken along line X-X of FIG. 8. For convenience of description, the present embodiment will be described with respect to differences from the previous embodiment.

Referring to FIGS. 7 through 10, the organic light-emitting display device 500 includes a substrate 501 in which a display area DA and a non-display area NA are defined.

In the display area DA, a plurality of pixels P1, P2, P3, P4, P5, and P6 are formed. Each of the pixels P1, P2, P3, P4, P5, and P6 includes a first electrode 510, the insulation pattern 580, an intermediate layer 514, and a second electrode 515. At least one of the plurality of pixels P1, P2, P3, P4, P5, and P6 includes a particle PT.

Hereinafter, each member will be described in detail.

A buffer layer 502 is formed on the substrate 501. The buffer layer 502 may be omitted.

The particle PT is present on the buffer layer 502. The particle PT is not included in a design condition of the organic light-emitting display device 500. Instead, the particle PT is undesirably formed during a manufacturing process. The particle PT may be an organic material, an inorganic material, or a metal material.

An insulating layer 504 is formed on the particle PT so as to cover the particle PT. The insulating layer 504 may be omitted.

Although not illustrated, the particle PT may be present on the insulating layer 504 or between the substrate 501 and the buffer layer 502 instead of on the buffer layer 502.

The first electrode 510 is formed on the insulating layer 504. The first electrode 510 includes a first region 511, a second region 512, and an opening region 510a. The first region 511 corresponds to the particle PT. The first region 511 has a protruding region that corresponds to the particle PT. The second region 512 is spaced apart from the first region 511. The second region 512 does not overlap with the particle PT, and is spaced apart from the first region 511 by the opening region 510a.

The insulation pattern 580 is formed on the first electrode 510. The insulation pattern 580 corresponds to the particle PT. The insulation pattern 580 on the first region 511 of the first electrode 510 overlaps with the particle PT and has a greater width than the particle PT. In more detail, the first region 511 of the first electrode 510 overlaps the particle PT and has a greater width than the particle PT. The opening region 510a of the first electrode 510 has a shape that surrounds the particle PT. The insulation pattern 580 has a greater width than the first region 511 so as to cover the first region 511 of the first electrode 510, and fills the opening region 510a. The insulation pattern 580 may contact a predetermined region of the second region 512 of the first electrode 510.

In FIGS. 8 and 9, the insulation pattern 580 is shown to have a quadrangular shape. In various implementations, the insulation pattern 580 may have one of various suitable shapes that overlap the particle PT and have a greater width than the particle PT.

Facing surfaces of the first region 511 and the second region 512, i.e., the surfaces of the first region 511 and the second region 512, which face across the opening region 510a, are cut surfaces. For example, the cut surfaces may be formed by using a fine cutting member such as a laser beam.

The intermediate layer 514 is formed on the insulation pattern 580. The intermediate layer 514 includes an organic emission layer (organic EML) to emit a visible ray. Because the intermediate layer 514 is formed on the insulation pattern 580, the intermediate layer 514 is spaced apart from the first region 511 of the first electrode 510 but contacts the second region 512 of the first electrode 510.

The second electrode 515 is formed on the intermediate layer 514. An encapsulation member (not shown) may be further formed on the second electrode 515. The encapsulation member protects the first electrode 510, the intermediate layer 514, or the second electrode 515 against moisture, foreign substances, shock, or the like.

In the organic light-emitting display device 500 according to the present embodiment, the insulation pattern 580 is formed between the first electrode 510 and the intermediate layer 514. The insulation pattern 580 may easily prevent a defect such as a dark spot due to the presence of the particle PT.

In more detail, the undesired particle PT may be present between the substrate 501 and the first electrode 510, and due to presence of the particle PT, the first electrode 510 has a protruding region at a position that corresponds to the particle PT. If the insulation pattern 580 were not included, the protruding region of the first electrode 510 could not only contact the intermediate layer 514 but also partially contact the second electrode 515 due to a height of the protruding region. As a result, a short circuit defect could occur between the first electrode 510 and the second electrode 515, and a defect such as a dark spot could occur in the corresponding pixel P1. That is, an entire region of the pixel P1 having the particle PT may not emit light.

However, according to the present embodiment, the insulation pattern 580 is formed on the first electrode 510 so as to correspond to the particle PT. Although the first electrode 510 has the protruding region, the protruding region contacts the insulation pattern 580, so that it may be possible to fundamentally prevent the protruding region of the first electrode 510 from contacting the intermediate layer 514 and the second electrode 515.

In particular, the first region 511 of the first electrode 510, which corresponds to the particle PT, is spaced apart from the second region 512 of the first electrode 510. The first region 511 does not contact the intermediate layer 514, and the second region 512 contacts the intermediate layer 514. Accordingly, the first region 511 in which emission does not occur is spaced apart from the second region 512 in which emission occurs, so that abnormal emission in the first region 511 may be fundamentally prevented, and a visible ray having an appropriate quality may be effectively emitted from the second region 512. Here, because the insulation pattern 580 fills the opening region 510a, the first region 511 is effectively and electrically isolated from the second region 512 and the intermediate layer 514.

Thus, although the particle PT is present, a defect such as a dark spot of the pixel P1 may be effectively prevented, so that an image quality characteristic of the organic light-emitting display device 500 may be easily improved.

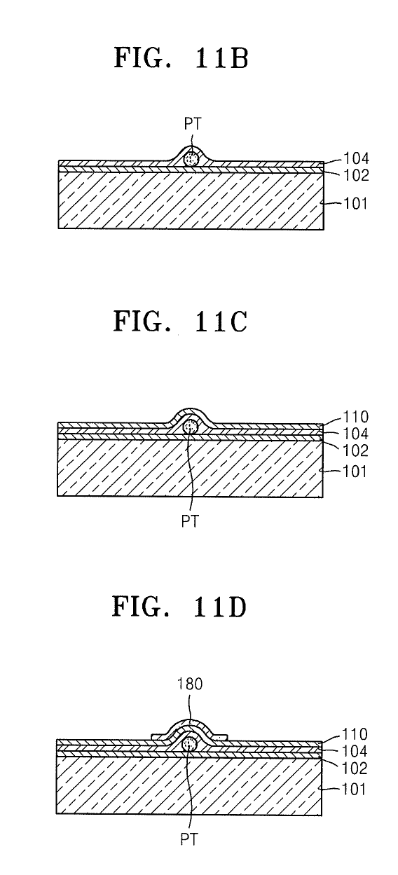

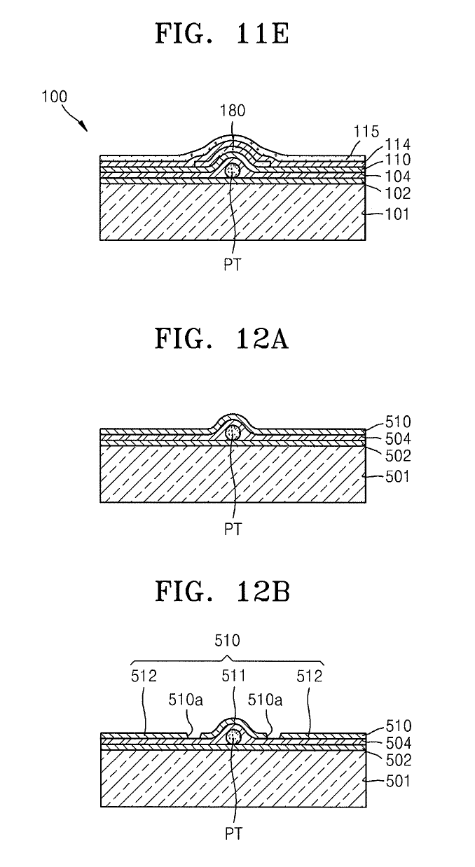

FIGS. 11A through 11E are cross-sectional views of stages of a method of manufacturing the organic light-emitting display device 100 of FIG. 1, according to an embodiment.

Referring to FIG. 11A, the buffer layer 102 is formed on the substrate 101. An undesired particle PT may be formed or deposited on the buffer layer 102. The particle PT may be formed on the substrate 101 and the buffer layer 102.

Referring to FIG. 11B, the insulating layer 104 is formed on the particle PT. Due to the presence of the particle PT, the insulating layer 104 is not flat and has a protruding region.

Referring to FIG. 11C, the first electrode 110 is formed on the insulating layer 104. The first electrode 110 is not flat due to presence of the particle PT formed therebelow and thus has a protruding shape. In particular, depending on a size of the particle PT, the first electrode 110 may have a large protruding region that corresponds to the particle PT.

Referring to FIG. 11D, the insulation pattern 180 is formed on the first electrode 110. Before the insulation pattern 180 is formed, a process of detecting the presence of the particle PT is first performed. That is, by performing a particle checking process, the existence and position of the particle PT are detected. By doing so, the insulation pattern 180 may be formed to overlap with the particle PT and to have an appropriate size.

Referring to FIG. 11E, the intermediate layer 114 is formed on the insulation pattern 180, and then the second electrode 115 is formed on the intermediate layer 114, so that the manufacture of the organic light-emitting display device 100 is completed.

According to the present embodiment, when the particle PT occurs below the first electrode 110, the occurrence of the particle is determined and then the insulation pattern 180 is formed on the first electrode 110, so that a pixel defect such as a dark spot may be effectively prevented, and an image quality characteristic of the organic light-emitting display device 100, may be easily improved.

Although not illustrated, the method according to the present embodiment may also be applied to the organic light-emitting display devices 200, 300, and 400 of FIGS. 4 through 6. For example, in the case of the organic light-emitting display device 400 of FIG. 6, after the first electrode 410 is formed and then the source electrode 407 and the drain electrode 408 are formed, the presence of the particle PT may be determined and then the insulation pattern 480 may be formed.

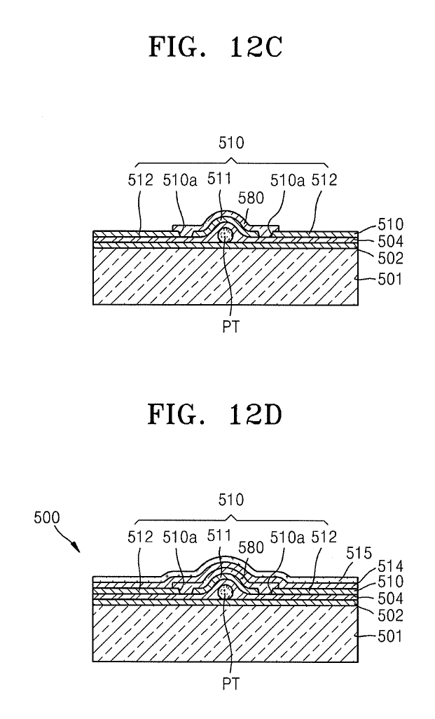

FIGS. 12A through 12D are cross-sectional views of stages of a method of manufacturing the organic light-emitting display device 500 of FIG. 10, according to an embodiment.

Referring to FIG. 12A, the buffer layer 502 is formed on the substrate 501. An undesired particle PT may be formed or deposited on the buffer layer 502. The particle PT may be present on the substrate 501 and the buffer layer 502. The insulating layer 504 is formed on the particle PT. Due to the presence of the particle PT, the insulating layer 504 is not flat and has a protruding region. Then, the first electrode 510 is formed on the insulating layer 504. The first electrode 510 is not flat due to the particle PT formed therebelow and thus has a protruding shape. In particular, as a size of the particle PT increases, the first electrode 510 has a large protruding region that corresponds to the particle PT.

Referring to FIG. 12B, the opening region 510a is formed in the first electrode 510, so that the first region 511 and the second region 512 are separated from each other. Before the first region 511 and the second region 512 are formed, a process of detecting the presence of the particle PT is first performed. That is, by performing a particle checking process, the existence and position of the particle PT are detected. By doing so, a target position for the opening region 510a may be exactly determined.

The first region 511 corresponds to the particle PT, and has a protruding region that corresponds to the particle PT. The second region 512 is spaced apart from the first region 511. In more detail, the second region 512 does not overlap with the particle PT, and is spaced apart from the first region 511 by the opening region 510a.

By using a cutting member such as a laser beam, it is possible to form the opening region 510a having a desired width in a desired position of the first electrode 510. That is, after the existence, a size, a shape, and the quantity of the particle PT are detected via the particle checking process, the opening region 510a is formed to have a shape that does not overlap with the particle PT and surrounds the particle PT.

After a cutting process to form the opening region 510a is performed, surfaces of the first region 511 and the second region 512, which face across the opening region 510a, are cut surfaces.

Various suitable cutting members may be used to form the opening region 510a.

Afterward, referring to FIG. 12C, the insulation pattern 580 is formed on the first electrode 510. In more detail, the insulation pattern 580 is formed to correspond to the particle PT. Also, the insulation pattern 580 on the first region 511 of the first electrode 510 overlaps with the particle PT and has a greater width than the particle PT. Also, the insulation pattern 580 has a greater width than the first region 511 so as to cover the first region 511 of the first electrode 510, and fills the opening region 510a. Also, the insulation pattern 580 may contact a predetermined region of the second region 512 of the first electrode 510.

Then, referring to FIG. 12D, the intermediate layer 514 is formed on the insulation pattern 580, and then the second electrode 515 is formed on the intermediate layer 514, so that the manufacture of the organic light-emitting display device 500 is completed.

According to the present embodiment, when the particle PT occurs below the first electrode 510, the occurrence may be determined and then the insulation pattern 580 is formed on the first electrode 510, so that a pixel defect such as a dark spot may be effectively prevented, and an image quality characteristic of the organic light-emitting display device 500 is easily improved.

In particular, the first region 511 of the first electrode 510, which corresponds to the particle PT, is spaced apart from the second region 512 of the first electrode 510. Also, the first region 511 does not contact the intermediate layer 514, and the second region 512 contacts the intermediate layer 514. Accordingly, the first region 511 in which emission does not occur is spaced apart from the second region 512 in which emission occurs, so that abnormal emission in the first region 511 may be fundamentally prevented, and a visible ray having an appropriate quality may be effectively emitted from the second region 512.

Although not illustrated, the method according to the present embodiment may also be applied to the organic light-emitting display devices 200, 300, and 400 of FIGS. 4 through 6. For example, in the case of the organic light-emitting display device 400 of FIG. 6, after the first electrode 410 is formed and then the source electrode 407 and the drain electrode 408 are formed, the presence of the particle PT may be determined and then, the insulation pattern 480 may be formed.

By way of summation and review, particles that are present in various locations of an organic light-emitting display device may affect an electrical characteristic between components of the organic light-emitting display device. For example, the particles may cause a defect such as a short circuit between the first and second electrodes.

According to embodiments, an insulation pattern may be formed so as to correspond to the particle. Accordingly, an image quality characteristic of the organic light-emitting display device may be improved.

While embodiments have been particularly shown and described with reference to exemplary embodiments thereof, it will be understood by those of ordinary skill in the art that various changes in form and details may be made therein without departing from the spirit and scope thereof as defined by the following claims.

What is claimed is:

1. An organic light-emitting display device, comprising:
a substrate;
a first electrode on the substrate;
a particle located between the substrate and the first electrode;
an insulation pattern that is on the first electrode and that corresponds to the particle;
an intermediate layer that is on the insulation pattern and that is electrically connected to the first electrode, the intermediate layer including an organic emission layer; and
a second electrode on the intermediate layer.

2. The organic light-emitting display device of claim 1, wherein the insulation pattern has a greater width than the particle such that the particle does not exceed the insulation pattern in size.

3. The organic light-emitting display device of claim 1, wherein:
the first electrode includes a protruding region corresponding to the particle, and
the insulation pattern covers the protruding region of the first electrode.

4. The organic light-emitting display device of claim 1, wherein:
the first electrode includes a first region, a second region, and an opening region,
the first region and the second region are spaced apart from each other by the opening region, and
the opening region has a greater width than the particle and surrounds the particle.

5. The organic light-emitting display device of claim 4, wherein:
the first region corresponds to the particle and is spaced apart from the intermediate layer, and
the second region contacts the intermediate layer.

6. The organic light-emitting display device of claim 4, wherein the insulation pattern fills the opening region.

7. An organic light-emitting display device, comprising:
a substrate in which a display area including a plurality of pixels, and a non-display area that surrounds the display area are defined, each of the plurality of pixels including a first electrode, an intermediate layer including an organic emission layer, and a second electrode;
a particle located in at least one of the plurality of pixels between the substrate and the first electrode; and
an insulation pattern that is on the first electrode and that corresponds to the particle.

8. The organic light-emitting display device of claim 7, wherein the insulation pattern has a greater width than the particle such that the particle does not exceed the insulation pattern in size.

9. The organic light-emitting display device of claim 7, wherein:
the first electrode includes a protruding region corresponding to the particle, and
the insulation pattern covers the protruding region of the first electrode.

10. The organic light-emitting display device of claim 7, wherein:
the first electrode includes a first region, a second region, and an opening region,
the first region and the second region are spaced apart from each other by the opening region, and
the opening region has a greater width than the particle and surrounds the particle.

11. The organic light-emitting display device of claim 10, wherein:
the first region corresponds to the particle and is spaced apart from the intermediate layer, and
the second region contacts the intermediate layer.

12. The organic light-emitting display device of claim 10, wherein the insulation pattern fills the opening region.

13. The organic light-emitting display device of claim 7, further comprising a thin film transistor (TFT) that is electrically connected to the first electrode of each of the plurality of pixels and that includes an active layer, a gate electrode, a source electrode, and a drain electrode.

14. The organic light-emitting display device of claim 7, wherein:
each pixel of the plurality of pixels includes a thin film transistor (TFT) that is electrically connected to the first electrode of the respective pixel and that includes an active layer, a gate electrode, a source electrode, and a drain electrode, and
wherein the first electrode is formed on the same layer as the gate electrode.

15. A method of manufacturing an organic light-emitting display device, the method comprising:
forming a first electrode on a substrate;
detecting the presence of a particle between the substrate and the first electrode;
forming an insulation pattern on the first electrode such that the insulation pattern corresponds to the particle;
forming an intermediate layer that is disposed on the insulation pattern and that is electrically connected to the first electrode, the intermediate layer including an organic emission layer; and
forming a second electrode on the intermediate layer.

16. The method of claim 15, wherein the detecting of the presence of the particle includes determining an existence, a size, a shape, and a position of the particle.

17. The method of claim 15, wherein the insulation pattern has a greater width than the particle such that the particle does not exceed the insulation pattern in size.

18. The method of claim 15, wherein:
the first electrode includes a protruding region corresponding to the particle, and
the insulation pattern covers the protruding region of the first electrode.

19. The method of claim 15, wherein:
the first electrode includes a first region, a second region, and an opening region,
the first region and the second region are spaced apart from each other by the opening region, and
the opening region has a greater width than the particle and surrounds the particle.

20. The method of claim 19, wherein the opening region is formed via a cutting process.

21. The method of claim 20, wherein the cutting process is performed using a laser beam.

22. The method of claim 19, wherein:
the first region corresponds to the particle and is spaced apart from the intermediate layer, and
the second region contacts the intermediate layer.

23. The method of claim 19, wherein the insulation pattern fills the opening region.

24. The method of claim 15, further comprising forming a thin film transistor (TFT) that is electrically connected to the first electrode and that includes an active layer, a gate electrode, a source electrode, and a drain electrode.

25. The method of claim 15, further comprising forming a TFT that is electrically connected to the first electrode and that includes an active layer, a gate electrode, a source electrode, and a drain electrode, and
wherein the first electrode is formed on the same layer as the gate electrode.

26. The method of claim 25, wherein the detecting of the particle is performed after the source electrode and the drain electrode are formed.
